(19) United States
(12) Patent Application Publication
(10) Pub. No.: US 2011/0199673 A1
(43) Pub. Date: Aug. 18, 2011

(54) INTEGRATED OPTICAL DEVICE AND OPTICAL PICKUP DEVICE USING THE SAME

(75) Inventors: Shingo OKAURA, Osaka (JP); Masaki Taniguchi, Kyoto (JP); Hideo Fukuda, Kyoto (JP)

(73) Assignee: PANASONIC CORPORATION, Osaka (JP)

(21) Appl. No.: 13/052,842

(22) Filed: Mar. 21, 2011

Related U.S. Application Data
(63) Continuation of application No. PCT/JP2010/004046, filed on Jun. 17, 2010.

(30) Foreign Application Priority Data
Feb. 15, 2010 (JP) 2010-029666

(51) Int. Cl. H01S 5/00

(52) U.S. Cl. 359/344

(57) ABSTRACT

An integrated optical device includes a plurality of semiconductor lasers which emit different wavelengths of laser light, a comparator circuit which compares voltages across terminals of the respective plurality of semiconductor lasers, and outputs a signal depending on the comparison result, a light-receiving element which outputs a photocurrent depending on the amounts of laser light emitted from the plurality of semiconductor lasers, and a current mirror circuit which switches between amplification and attenuation with respect to the photocurrent output from the light-receiving element based on the signal output from the comparator circuit, and outputs a monitor signal.

### CROSS-REFERENCE TO RELATED APPLICATION

This is a continuation of PCT International Application PCT/JP2010/004046 filed on Jun. 17, 2010, which claims priority to Japanese Patent Application No. 2010-029666 filed on Feb. 15, 2010. The disclosures of these applications including the specifications, the drawings, and the claims are hereby incorporated by reference in its entirety.

### BACKGROUND

The technology disclosed herein relates to integrated optical devices which receive a plurality of different wavelengths of light, and to optical pickup devices including such integrated optical devices.

High-capacity randomly-accessible digital media include optical disks such as compact discs (CDs), digital versatile discs (DVDs), and blu-ray discs (BDs). For reading and/or writing data from and/or to the optical disks (CDs, DVDs, and BDs), optical pickup devices are used. In an optical pickup device, different semiconductor lasers are used depending on the information capacities of the optical disks (CDs, DVDs, and BDs), and thus a plurality of semiconductor lasers are required which emit different wavelengths of light, including an infrared laser (λ=780 nm), a red laser (λ=650 nm), and/or a blue laser (λ=410 nm). In order to stabilize the output power of such semiconductor lasers while reading or writing data, an optical pickup device includes one or more automatic power control (APC) circuits, each of which monitors light output from a semiconductor laser by a light-receiving element and provides power control of the semiconductor laser by means of a monitor signal.

An optical pickup device according to a first background technology receives, by a common light-receiving element, light output from a plurality of semiconductor lasers respectively emitting different wavelengths of light, generates monitor signals in a current mirror circuit from a photocurrent output from the light-receiving element, and outputs the monitor signals to the respective APC circuits. Based on the monitor signals with respect to the semiconductor lasers, the respective APC circuits provide power control of the plurality of semiconductor lasers. (See, e.g., FIG. 2 of Japanese Patent Publication No. 2002-133692.)

An optical pickup device using a plurality of semiconductor lasers can also use APC circuits each of which provides power control of a semiconductor laser based on a monitor signal on the corresponding semiconductor laser. Thus, basically, an APC circuit which has been used in an optical pickup device having a single semiconductor laser can be used without change, thereby allowing a technical and a cost burdens to be reduced. In particular, if semiconductor lasers or a light-receiving element for monitoring is included in an optical head together with an optical system, and if APC circuits are included in the head driving device, then only a design change is required such that, for example, current mirror circuits are added and/or changed, and no design change is needed in the side of the head driving device including the APC circuits.

An optical pickup device according to a second background technology includes a plurality of variable resistors respectively corresponding to a plurality of semiconductor lasers, a light detection means supporting the plurality of semiconductor lasers, and a power stabilization means which provides power control of the semiconductor lasers so that the optical power output from the semiconductor lasers remains constant. The optical pickup device is set so that the optical power output from the semiconductor lasers corresponding to the respective variable resistors is maintained at a predetermined level by changing the resistances of the respective variable resistors. (See, e.g., FIG. 1 of Japanese Patent Publication No. 2001-085786.)

Since this APC circuit can provide power control of a plurality of semiconductor lasers by a single unit, the size of a device itself can be reduced compared with a case where APC circuits are independently provided for a plurality of semiconductor lasers. Moreover, the number of parts can be reduced, thereby allowing the manufacturing cost to be reduced.

### SUMMARY

According to the first background technology described above, in order to provide power control of the plurality of semiconductor lasers, the optical pickup device includes APC circuits respectively corresponding to the semiconductor lasers, generates monitor signals in the current mirror circuit from a photocurrent from the light-receiving element, and outputs the monitor signals, different from one another, from the current mirror circuit to the respective APC circuits. This configuration causes the number of monitor signal terminals for outputting the monitor signals to the APC circuits to be increased, and thus the chip size of the integrated optical device to be increased. In addition, since the value of the mirror ratio of the current mirror circuit is designed so as to support APC circuits which have been used in an optical pickup device including a single semiconductor laser, the current values of the monitor signals output from the current mirror circuit are different from one another, thereby requiring a test standard to be provided for each monitor signal, and also causing the number of tests to be increased. Thus, the manufacturing cost is increased.

According to the second background technology described above, since the current values of the monitor signals output from the light-receiving element are different depending on the semiconductor laser in operation, power control of the plurality of semiconductor lasers by a single APC circuit requires a plurality of variable resistors respectively corresponding to the plurality of semiconductor lasers, thereby causing the configuration of the optical pickup device to be more complex.

In view of the foregoing, it is an object of the present invention to provide an integrated optical device in which the value of monitor current from the light-receiving element can be automatically kept constant without depending on the wavelengths of the light output from the semiconductor lasers, and to provide an optical pickup device using the integrated optical device.

In order to solve these problems, an integrated optical device according to one aspect of the present invention includes a plurality of semiconductor lasers configured to emit different wavelengths of laser light, a comparison circuit configured to compare voltages across terminals of the respective plurality of semiconductor lasers, and to output a signal depending on a comparison result, a light-receiving element configured to output a photocurrent depending on respective amounts of laser light emitted from the plurality of semiconductor lasers, and a photocurrent amplifier configured to switch between amplification and attenuation with respect to the photocurrent output from the light-receiving element based on the signal output from the comparison circuit, and to output a monitor signal.

In an integrated optical device according to one aspect of the present invention, the photocurrent amplifier may be a current mirror circuit whose input terminal is coupled to the light-receiving element, and change a value of a mirror ratio of the current mirror circuit by switching either one of a resistance value of a first emitter resistor coupled to an emitter of a transistor on the input side of the current mirror circuit or a resistance value of a second emitter resistor coupled to an emitter of a transistor on the output side of the current mirror circuit, based on the signal output from the comparison circuit.

In the above case, the first emitter resistor or the second emitter resistor may be formed by a plurality of resistors coupled in parallel, at least one of the plurality of resistors being coupled through a switching element, and the switching element turns on and off based on the signal output from the comparison circuit to change the value of the mirror ratio of the current mirror circuit.

In the above case, the first emitter resistor or the second emitter resistor may be formed by a plurality of resistors coupled in series, at least one of the plurality of resistors being coupled in parallel with a switching element, and the switching element turns on and off based on the signal output from the comparison circuit to change the value of the mirror ratio of the current mirror circuit.

In an integrated optical device according to one aspect of the present invention, the photocurrent amplifier may be a combination of a plurality of current mirror circuits respectively having different values of mirror ratios; respective inputs of the plurality of current mirror circuits are coupled to the light-receiving element through switching elements respectively coupled to the plurality of current mirror circuits on a one-to-one basis, and respective outputs of the plurality of current mirror circuits are coupled together; and the switching elements turn on and off based on the signal output from the comparison circuit to select one of the plurality of current mirror circuits to change the value of the effective mirror ratio.

In an integrated optical device according to one aspect of the present invention, the photocurrent amplifier may output a current of a constant value with respect to the respective wavelengths of the plurality of semiconductor lasers.

In an integrated optical device according to one aspect of the present invention, the photocurrent amplifier may have only one output terminal.

An optical pickup device according to one aspect of the present invention includes the integrated optical device according to the one aspect of the present invention.

Thus, according to an integrated optical device of one aspect of the present invention, the monitor current from the light-receiving element can be kept constant without depending on the wavelengths of the light emitted from the plurality of semiconductor lasers. Accordingly, test standards can be standardized, and at the same time, the number of tests can be reduced. As a result, the manufacturing cost can be reduced, and also, the chip size can be reduced due to the elimination of the need to provide separate output terminals for monitor currents. Moreover, since with an integrated optical device of one aspect of the present invention, the value of the monitor current is kept constant without depending on which semiconductor laser is emitting light, the configurations of an APC circuit and an optical pickup device can be simplified. Furthermore, since the value of the mirror ratio of the current mirror circuit can be automatically switched by monitoring the terminals of the semiconductor lasers, no switching signals are required from the outside world.

### BRIEF DESCRIPTION OF THE DRAWINGS

FIG. 1 is a circuit diagram illustrating a configuration of an integrated optical device according to the first embodiment of the present invention.

FIG. 2 is a circuit diagram illustrating a configuration of a variation of the integrated optical device according to the first embodiment of the present invention.

FIG. 3 is a circuit diagram illustrating a configuration of an integrated optical device according to the second embodiment of the present invention.

FIG. 4 is a circuit diagram illustrating a configuration of an integrated optical device according to the third embodiment of the present invention.

FIG. 5 is a schematic diagram illustrating an example configuration of an optical pickup device using an integrated optical device according to the fourth embodiment of the present invention.

FIG. 6 is a circuit diagram illustrating the connection arrangement of the integrated optical device and APC circuits, according to the fourth embodiment of the present invention.

### DETAILED DESCRIPTION

Example embodiments of the present invention will be described below with reference to the drawings. It should be understood that the accompanying drawings and the detailed description are intended to clearly explain the technical spirit of the present invention, and after understanding the preferred embodiments of the present invention, those skilled in the art can make various modifications and additions according to the technologies disclosed by the present invention without departing from the technical spirit and scope of the present invention.

### First Embodiment

FIG. 1 illustrates a configuration of an integrated optical device according to the first embodiment of the present invention.

As shown in FIG. 1, the integrated optical device according to this embodiment is typically used in an optical pickup device for reading and writing records from and to an optical recording medium (not shown). The integrated optical device includes a red semiconductor laser 101, an infrared semiconductor laser 102, a comparator circuit 105 which compares voltages across terminals of the respective semiconductor lasers and outputs a signal depending on the comparison result, a switching circuit 112, a light-receiving element 106, and a current mirror circuit 107.

Each of the red and the infrared semiconductor lasers 101 and 102 emits a laser beam to the unshown optical recording medium. The respective cathode terminals of the red and the infrared semiconductor lasers 101 and 102 are coupled to ground. The light-receiving element 106 is a photodiode, and receives light output from the semiconductor lasers and then outputs a photocurrent. The comparator circuit 105 outputs a signal depending on a result generated by comparing voltages at the anode terminal 103 of the red semiconductor laser 101 and at the anode terminal 104 of the infrared semiconductor laser 102. The switching circuit 112 turns on and off according to the signal from the comparator circuit 105. The current mirror circuit 107 includes resistors 108-110 and transistors 113 and 114, and amplifies or attenuates the photocurrent output from the light-receiving element 106 depending on the value of the mirror ratio switched by on-off switching of the switching circuit 112, and then outputs the resultant current as a monitor current from a monitor current output terminal 111.

The operation of the integrated optical device according to this embodiment shown in FIG. 1 will now be described. When the red semiconductor laser 101 is emitting light, the switching circuit 112 is in an ON state due to the signal output from the comparator circuit 105, and thus a current also flows through the resistor 109. Therefore, the value of the mirror ratio is determined by a combination of the resistors 109 and 110 and the resistor 108, and the monitor current is output from the monitor current output terminal 111. Meanwhile, when the infrared semiconductor laser 102 is emitting light, the switching circuit 112 is in an OFF state, and thus current does not flow through the resistor 109. Therefore, the value of the mirror ratio is determined by the resistors 108 and 110, and the monitor current is output from the monitor current output terminal 111.

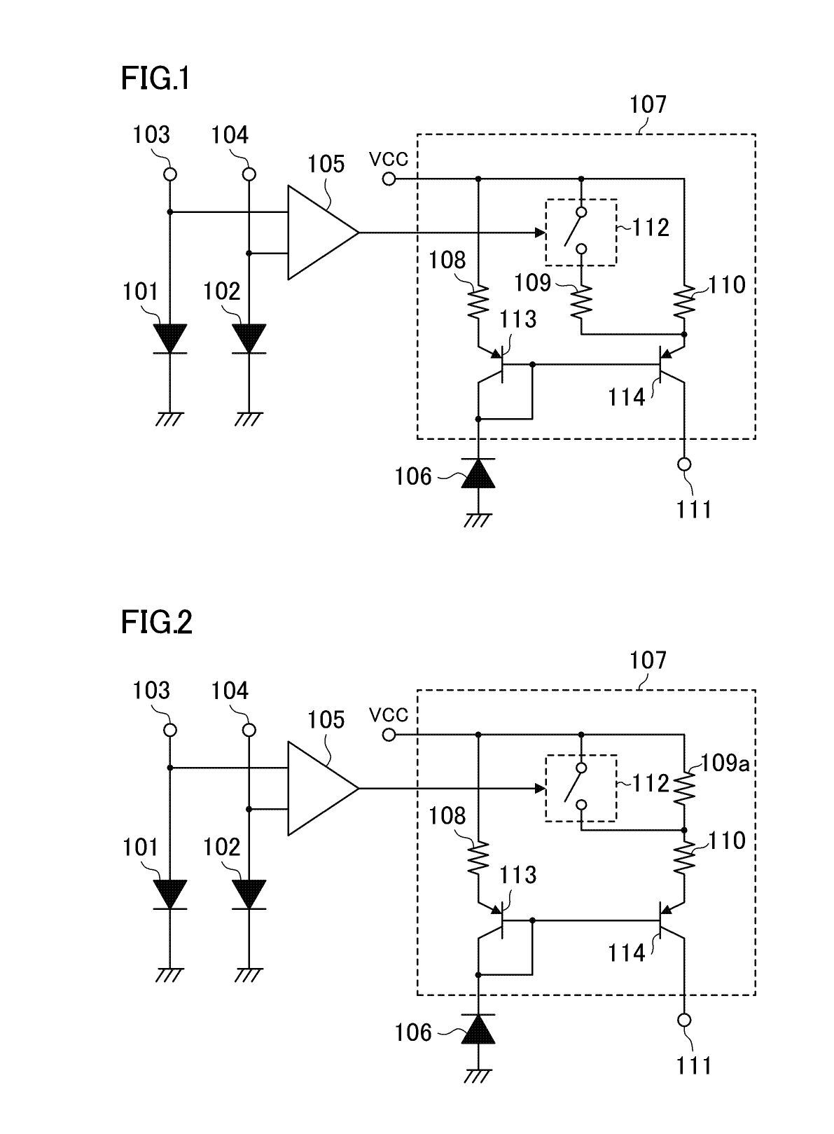

FIG. 2 illustrates a configuration of a variation of the integrated optical device according to the first embodiment of the present invention.

As shown in FIG. 2, an integrated optical device may have a configuration in which a resistor 109a and the resistor 110 are coupled in series, and the switching circuit 112 is coupled in parallel with the resistor 109a, instead of the configuration of the integrated optical device shown in FIG. 1.

With such a configuration, when the switching circuit 112 is in an OFF state, a current flows through the resistor 109a, and thus the value of the mirror ratio can be determined by the combination of the resistors 109a and 110 and the resistor 108. Meanwhile, when the switching circuit 112 is in an ON state, current does not flow through the resistor 109a, and thus the value of the mirror ratio can be determined by the resistors 110 and 108.

In the configurations of the integrated optical device shown in FIGS. 1 and 2, the values of the mirror ratio in respective cases where the red and the infrared semiconductor lasers 101 and 102 emit light are determined by setting the resistance values of the resistors 108, 109, 109a, and 110 of the current mirror circuit 107 so that the monitor current from the monitor current output terminal 111 is kept the same.

Although, with respect to the configurations of the integrated optical device shown in FIGS. 1 and 2, the foregoing description discusses the configurations in which the resistors 109 and 109a are coupled to the emitter resistor 110 provided in the output side of the current mirror circuit 107, the resistors 109 and 109a may be coupled to the emitter resistor 108 provided in the input side. Such a configuration also allows an operation similar to the foregoing.

Note that, in the configurations of the integrated optical device shown in FIGS. 1 and 2, a bipolar transistor or a field effect transistor (FET) may be used as the switching circuit 112. If a bipolar transistor is used to form the switching circuit 112, on-off switching of the switching circuit 112 is controlled by changing the base voltage of the bipolar transistor or by changing the flow of the base current by means of the signal output from the comparator circuit 105. Meanwhile, if an FET is used to form the switching circuit 112, on-off switching of the switching circuit 112 is controlled by changing the gate voltage of the FET by means of the signal output from the comparator circuit 105.

As described above, according to the integrated optical device of the first embodiment of the present invention, monitoring the respective terminals 103 and 104 of the red and the infrared semiconductor lasers 101 and 102, and automatically switching the value of the mirror ratio of the current mirror circuit 107 allows the value of the monitor current output from the monitor current output terminal 111 to be kept constant. Thus, the manufacturing cost can be reduced through reduction in the number of tests, and at the same time, APC circuits and optical pickup devices can be simplified.

### Second Embodiment

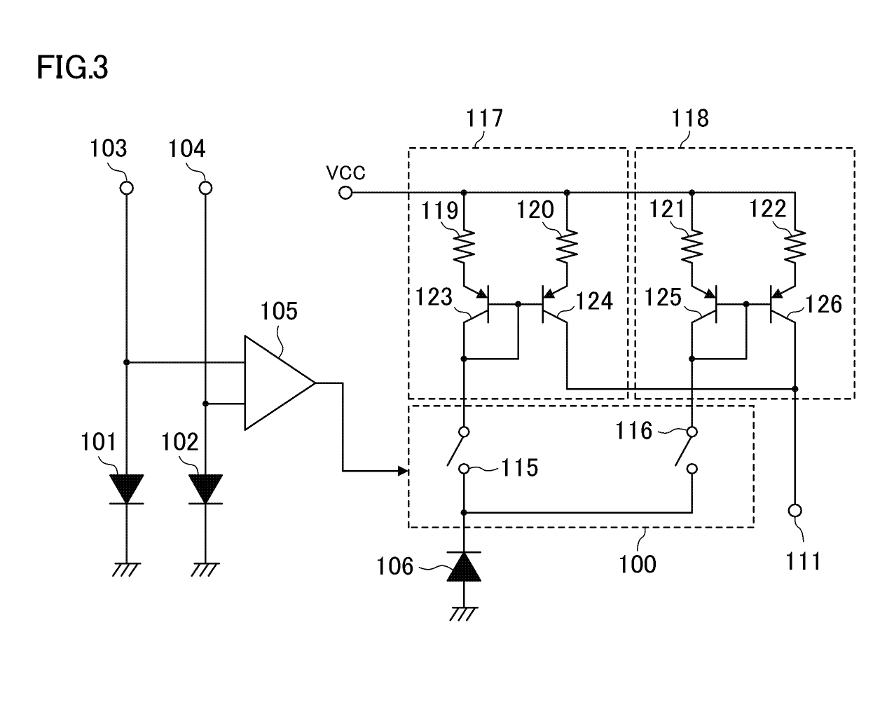

FIG. 3 illustrates a configuration of an integrated optical device according to the second embodiment of the present invention.

As shown in FIG. 3, the integrated optical device according to this embodiment is typically used in an optical pickup device for reading and writing records from and to an optical recording medium (not shown). The integrated optical device includes a red semiconductor laser 101, an infrared semiconductor laser 102, a comparator circuit 105 which compares voltages across terminals of the respective semiconductor lasers and outputs a signal depending on the comparison result, a switching circuit 100, a light-receiving element 106, and two current mirror circuits 117 and 118.

Here, the switching circuit 100 includes switching elements 115 and 116, and turns each of the switching elements 115 and 116 on and off according to the signal from the comparator circuit 105. The current mirror circuit in operation is switched by on-off switching of the switching circuit 100 between the current mirror circuit 117, which includes resistors 119 and 120 and transistors 123 and 124, and the current mirror circuit 118, which includes resistors 121 and 122 and transistors 125 and 126, thereby amplifies or attenuates the photocurrent output from the light-receiving element 106, and outputs the resultant current as a monitor current from a monitor current output terminal 111. Note that, in FIG. 3, the same reference characters as those shown in FIG. 1 are used to represent equivalent components, and the explanation thereof will not be repeated.

The operation of the integrated optical device according to this embodiment shown in FIG. 3 will be described below. When the red semiconductor laser 101 is emitting light, a signal corresponding to the red semiconductor laser 101 is input from the comparator circuit 105 to the switching circuit 100, and the switching element 115 coupled to the current mirror circuit 117 turns on; thus, a photocurrent flows from the light-receiving element 106 to the current mirror circuit 117. On the other hand, the switching element 116 coupled to the current mirror circuit 118 turns off, and thus photocurrent does not flow to the current mirror circuit 118. Therefore, the value of the mirror ratio of the current mirror circuit 117 is determined by the resistors 119 and 120, and the monitor current is output from the monitor current output terminal 111.

Meanwhile, when the infrared semiconductor laser 102 is emitting light, a signal corresponding to the infrared semiconductor laser 102 is input from the comparator circuit 105 to the switching circuit 100, and the switching element 116 coupled to the current mirror circuit 118 turns on; thus, a photocurrent flows from the light-receiving element 106 to the current mirror circuit 118. On the other hand, the switching element 115 coupled to the current mirror circuit 117 turns off, and thus photocurrent does not flow to the current mirror circuit 117. Therefore, the value of the mirror ratio of the current mirror circuit 118 is determined by the resistors 121 and 122, and the monitor current is output from the monitor current output terminal 111.

In the configuration of the integrated optical device shown in FIG. 3, the values of the mirror ratios of the current mirror circuits 117 and 118 respectively corresponding to the red and the infrared semiconductor lasers 101 and 102 are determined by setting the resistance values of the resistors 119-122 of the current mirror circuits 117 and 118 so that the monitor current from the monitor current output terminal 111 is kept constant.

Note that, in the configuration of the integrated optical device shown in FIG. 3, a bipolar transistor or an FET may be used as the switching circuit 100. If a bipolar transistor is used to form the switching circuit 100, on-off switching of the switching circuit 100 is controlled by changing the base voltage of the bipolar transistor or by changing the flow of the base current by means of the signal output from the comparator circuit 105. Meanwhile, if an FET is used to form the switching circuit 100, on-off switching of the switching circuit 100 is controlled by changing the gate voltage of the FET by means of the signal output from the comparator circuit 105.

As described above, according to the integrated optical device of the second embodiment of the present invention, and similarly to that of the first embodiment, monitoring the respective terminals 103 and 104 of the red and the infrared semiconductor lasers 101 and 102, and automatically switching between the current mirror circuits 117 and 118 allows the value of the mirror ratio to be switched, and thus the value of the monitor current output from the monitor current output terminal 111 to be kept constant. Accordingly, the manufacturing cost can be reduced through reduction in the number of tests, and at the same time, APC circuits and optical pickup devices can be simplified. Moreover, in this embodiment, the switching circuit 100 is not coupled to the emitter resistors of the current mirror circuits 117 and 118; therefore, no variation is introduced in the value of the mirror ratio, and a stable monitor current can be output from the monitor current output terminal 111. Thus, compared with the first embodiment, this embodiment provides a more accurate value of the mirror ratio, thereby allowing more stable APC control to be provided.

### Third Embodiment

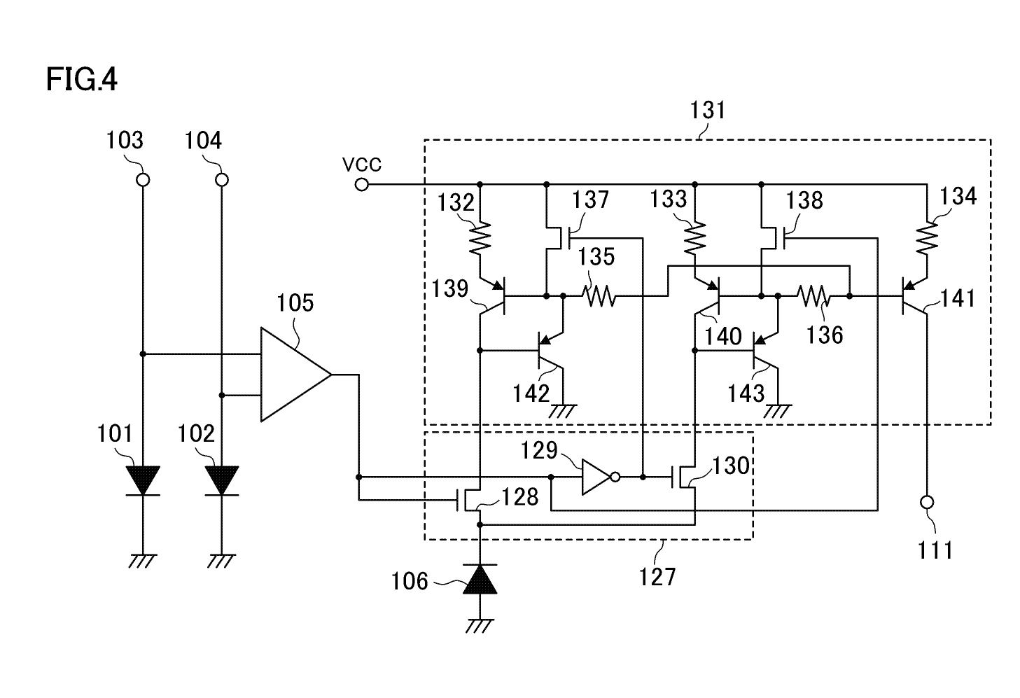

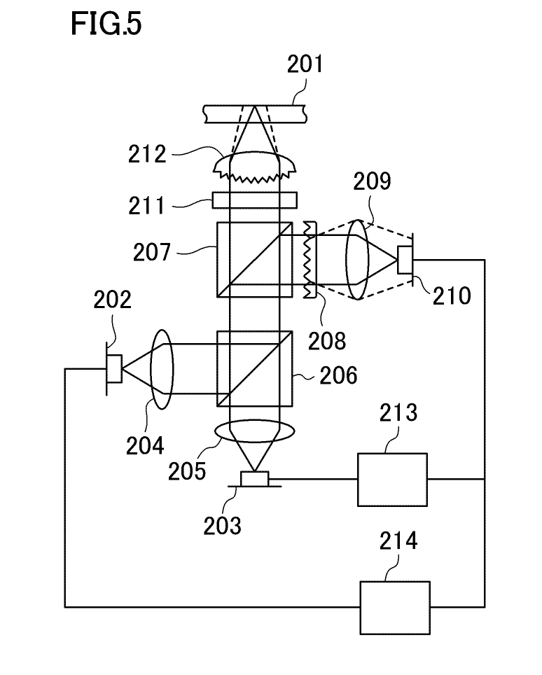

FIG. 4 illustrates a configuration of an integrated optical device according to the third embodiment of the present invention.

As shown in FIG. 4, the integrated optical device according to this embodiment is typically used in an optical pickup device for reading and writing records from and to an optical recording medium (not shown). The integrated optical device includes a red semiconductor laser 101, an infrared semiconductor laser 102, a comparator circuit 105 which compares voltages across terminals of the respective semiconductor lasers and outputs a signal depending on the comparison result, a switching circuit 127, a light-receiving element 106, and a current mirror circuit 131.

Here, the switching circuit 127 includes transistors 128 and 130 and an inverter circuit 129, and turns on and off according to the signal from the comparator circuit 105. The current mirror circuit 131 includes resistors 132-136 and transistors 137-143; and the current mirror circuit 131 has a configuration such that the two current mirror circuits 117 and 118 shown in FIG. 3 are implemented by one current mirror circuit 131. Based on switching of the value of the mirror ratio by the on-off switching of the switching circuit 127, the current mirror circuit 131 amplifies or attenuates the photocurrent output from the light-receiving element 106, and then outputs the resultant current as a monitor current from a monitor current output terminal 111. Note that, in FIG. 4, the same reference characters as those shown in FIG. 1 are used to represent equivalent components, and the explanation thereof will not be repeated.

The operation of the integrated optical device according to this embodiment shown in FIG. 4 will be described below. When the red semiconductor laser 101 is emitting light, the photocurrent output from the light-receiving element 106 does not flow through the resistor 133 of the current mirror circuit 131, but flows only through the resistor 132 due to the operation of the comparator circuit 105 and the switching circuit 127. Therefore, the value of the mirror ratio of the current mirror circuit 131 is determined by the resistors 132 and 134, and the monitor current is output from the monitor current output terminal 111. Meanwhile, when the infrared semiconductor laser 102 is emitting light, the photocurrent output from the light-receiving element 106 does not flow through the resistor 132 of the current mirror circuit 131, but flows only through the resistor 133 due to the operation of the comparator circuit 105 and the switching circuit 127. Therefore, the value of the mirror ratio of the current mirror circuit 131 is determined by the resistors 133 and 134, and the monitor current is output from the monitor current output terminal 111.

In the configuration of the integrated optical device shown in FIG. 4, the values of the mirror ratio in respective cases where the red and the infrared semiconductor lasers 101 and 102 emit light are determined by setting the resistance values of the resistors 132 and 133 of the current mirror circuit 131 so that the monitor current from the monitor current output terminal 111 is kept the same.

As described above, according to the integrated optical device of the third embodiment of the present invention, and similarly to that of the first embodiment, monitoring the respective terminals 103 and 104 of the red and the infrared semiconductor lasers 101 and 102, and automatically switching the value of the mirror ratio of the current mirror circuit 131 allows the value of the monitor current output from the output terminal 111 to be kept constant. Thus, the manufacturing cost can be reduced through reduction in the number of tests, and at the same time, APC circuits and optical pickup devices can be simplified. Moreover, in this embodiment, the switching circuit 127 is not coupled to the emitter resistor of the current mirror circuit 131; therefore, no variation is introduced in the value of the mirror ratio, and a stable monitor current can be output from the monitor current output terminal 111, similarly to the second embodiment. Thus, compared with the first embodiment, this embodiment provides a more accurate value of the mirror ratio, thereby allowing more stable APC control. In addition to this, since this embodiment eliminates the necessity of dividing the current mirror circuit as is done in the second embodiment, an even higher level of integration can be provided for a circuit, and thus an integrated optical device having a smaller size can be provided.

### Fourth Embodiment

FIG. 5 illustrates an example configuration of an optical pickup device using an integrated optical device according to the fourth embodiment of the present invention.

As shown in FIG. 5, the optical pickup device according to this embodiment is an optical pickup device which can properly record and/or reproduce information on and/or from optical information-recording media having protective substrates of different thicknesses (e.g., BDs, high-definition DVDs (HD-DVDs), DVDs, CDs, etc.), and includes a semiconductor laser 202 capable of emitting light flux having a wavelength of, for example, 350-450 nm, a device called “two-laser one-package” 203 including both a semiconductor laser capable of emitting light flux having a wavelength of, for example, 600-700 nm and a semiconductor laser capable of emitting light flux having a wavelength of, for example, 700-800 nm, collimating lenses 204 and 205, a dichroic prism 206, a polarizing beam splitter 207, a diffractive element 208, a monitor lens 209, a monitor-detector 210 which serves as a monitor element, a quarter wavelength plate 211, and an objective lens 212 held so that the objective lens 212 can be driven by an actuator.

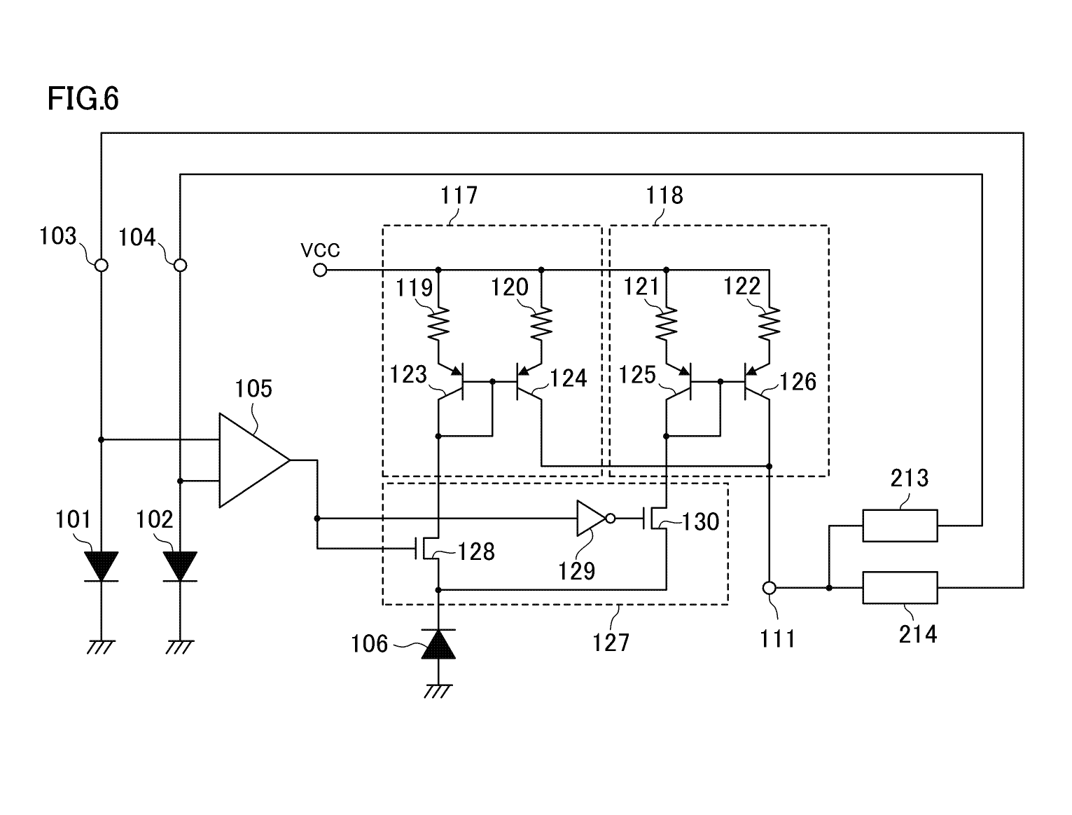

Here, the monitor-detector 210 shown in FIG. 5 corresponds to the integrated optical device, except for the semiconductor lasers, of each of the illustrated embodiments, and any integrated optical device can be used as appropriate. FIG. 6 illustrates the connection arrangement of the integrated optical device and APC circuits 213 and 214, using as an example a combination of the current mirror circuits 117 and 118 according to the second embodiment and the switching circuit 127 according to the third embodiment.

As shown in FIG. 6, the optical pickup device includes a red semiconductor laser 101, an infrared semiconductor laser 102, a comparator circuit 105, the switching circuit 127, the current mirror circuits 117 and 118, and the APC circuits 213 and 214.

The operation of the optical pickup device shown in FIG. 6 will be described below. When the red semiconductor laser 101 or the infrared semiconductor laser 102 emits light, a signal from the comparator circuit 105 and an operation of the switching circuit 127 causes the current mirror circuit to which the photocurrent output from the light-receiving element 106 flows to be switched between the current mirror circuits 117 and 118. A monitor current output from a monitor current output terminal 111 is input to the APC circuits 213 and 214, and then the APC circuits 213 and 214 provide control so that the output of the red or the infrared semiconductor laser 101 or 102 will be kept constant.

As described above, according to the optical pickup device of this embodiment, the use of an integrated optical device of the present invention allows same APC circuits to be used as when a single-wavelength semiconductor laser is used. Moreover, since there is only a single output terminal provided for the APC circuits, an optical pickup device having a simple configuration can be achieved.

The integrated optical devices of the present invention keep the monitor current from the light-receiving element constant without depending on the wavelengths of the light emitted from the plurality of semiconductor lasers, and thus are useful for optical pickup devices.

What is claimed is:

1. An integrated optical device, comprising:
a plurality of semiconductor lasers configured to emit different wavelengths of laser light;
a comparison circuit configured to compare voltages across terminals of the respective plurality of semiconductor lasers, and to output a signal depending on a comparison result;
a light-receiving element configured to output a photocurrent depending on respective amounts of laser light emitted from the plurality of semiconductor lasers; and
a photocurrent amplifier configured to switch between amplification and attenuation with respect to the photocurrent output from the light-receiving element based on the signal output from the comparison circuit, and to output a monitor signal.

2. The integrated optical device of claim 1, wherein
the photocurrent amplifier is a current mirror circuit whose input terminal is coupled to the light-receiving element, and changes a value of a mirror ratio of the current mirror circuit by switching either one of a resistance value of a first emitter resistor coupled to an emitter of a transistor on the input side of the current mirror circuit or a resistance value of a second emitter resistor coupled to an emitter of a transistor on the output side of the current mirror circuit, based on the signal output from the comparison circuit.

3. The integrated optical device of claim 2, wherein
the first emitter resistor or the second emitter resistor is formed by a plurality of resistors coupled in parallel, at least one of the plurality of resistors being coupled through a switching element, and
the switching element turns on and off based on the signal output from the comparison circuit to change the value of the mirror ratio of the current mirror circuit.

4. The integrated optical device of claim 2, wherein
the first emitter resistor or the second emitter resistor is formed by a plurality of resistors coupled in series, at least one of the plurality of resistors being coupled in parallel with a switching element, and
the switching element turns on and off based on the signal output from the comparison circuit to change the value of the mirror ratio of the current mirror circuit.

5. The integrated optical device of claim 1, wherein
the photocurrent amplifier is a combination of a plurality of current mirror circuits respectively having different values of mirror ratios;
respective inputs of the plurality of current mirror circuits are coupled to the light-receiving element through switching elements respectively coupled to the plurality of current mirror circuits on a one-to-one basis, and respective outputs of the plurality of current mirror circuits are coupled together; and
the switching elements turn on and off based on the signal output from the comparison circuit to select one of the plurality of current mirror circuits to change the effective value of mirror ratio.

6. The integrated optical device of claim 1, wherein
the photocurrent amplifier outputs a current of a constant value with respect to the respective wavelengths of the plurality of semiconductor lasers.

7. The integrated optical device of claim 1, wherein
the photocurrent amplifier has only one output terminal.

8. An optical pickup device, comprising:
the integrated optical device of claim 1.
